(19) United States
(12) Patent Application Publication
(10) Pub. No.: US 2004/0042181 A1
(43) Pub. Date: Mar. 4, 2004

(54) Thermoelectric module and process for producing the same

(75) Inventor: Koichi Nagasaki, Kokubu (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 10/603,570

(22) Filed: Jun. 25, 2003

(30) Foreign Application Priority Data
Jun. 26, 2002 (JP) 2002-186853

(51) Int. Cl. H05K 7/16

(52) U.S. Cl. 361/725

(57) ABSTRACT

A thermoelectric module comprising support substrates, a plurality of wiring conductors formed on the opposing surfaces of the support substrates, a plurality of thermoelectric elements, and solder layers formed between said wiring conductors and said thermoelectric elements, wherein the total projected area (Sv) of voids contained in said solder layers projected onto the surfaces of the support substrates on the side where the solder layers are in contact via the wiring conductors is from 1 to 20% of the total area (St) of the surfaces on where the solder layers are in contact with the wiring conductors.

### BACKGROUND OF THE INVENTION

1. Field of the Invention The present invention relates to a thermoelectric module having excellent thermoelectric characteristics that can be used for cooling heat-generating members such as semiconductors and optical integrated circuits, and to a process for producing the same.

2. Description of the Related Art

A thermoelectric module utilizing Peltier effect comprises, as shown in FIG. 1, wiring conductors 3 and 4 formed on both opposing surfaces of support substrates 1 and 2, and thermoelectric elements 5 that are held by the support substrates 1 and 2 via the wiring conductors 3 and 4.

A plurality of thermoelectric elements 5 include N-type thermoelectric elements 5a and P-type thermoelectric elements 5b which are alternately arranged, electrically connected in series through the wiring conductors 3 and 4, and are further connected to external connection terminals 9. By applying a DC voltage on the thermoelectric elements 5 from an external unit through external wirings connected to the external connection terminals 9, further, the surfaces of the support substrates 1 and 2 work to absorb the heat or generate the heat depending on the direction of electric current.

The wiring conductors 3 and 4 are usually copper electrodes to withstand heavy currents, and are joined to the thermoelectric elements 5 through solder layers.

The above thermoelectric module is simple in the structure, is easy to handle, maintains stable characteristics, and is drawing attention in regard to utilizing it over a wide range of applications.

In particular, it is small and is capable of accomplishing local cooling and is further capable of precisely controlling the temperature near at room temperature. Because of these reasons, the above thermoelectric module has been used for devices that require precise control to maintain a constant temperature (semiconductor lasers, optical integrated circuits, etc.) and small refrigerators.

As means for producing such a small thermoelectric module, there has been employed a method wherein starting powders of the N-type thermoelectric elements 5a and of the P-type thermoelectric elements 5b are hot- pressed to obtain sintered products or crystals thereof which are, then, sliced into a predetermined thickness, and the sliced materials are plated with nickel, and are diced into chips to thereby obtain N-type thermoelectric elements 5a and P-type thermoelectric elements 5b (see, for example, Japanese Unexamined Patent Publication (Kokai) No. 106478/1989).

As for the production of a thermoelectric module by using the N-type thermoelectric elements 5a and the P- type thermoelectric elements 5b, Japanese Unexamined Patent Publication (Kokai) No. 215005/1998) discloses a production of thermoelectric elements by applying a solder paste onto a plurality of wiring conductors 3 that play the role of electrodes, alternately placing the chip-like N-type thermoelectric elements 5a and P-type thermoelectric elements 5b thereon, applying a solder paste on the other wiring conductors 4, holding them by support substrates 2 and, then, reflowing the solder paste in a solder reflow furnace.

According to the method of producing the thermoelectric elements disclosed in the above Japanese Unexamined Patent Publication (Kokai) No. 215005/1998, however, the wiring conductors on the support substrates are firmly coupled to the thermoelectric elements by using a solder. Therefore, cracks develop in the solder layers and in the thermoelectric elements after used for extended periods of time, and the thermoelectric module exhibits deteriorating performance.

That is, with the conventional thermoelectric modules, cracks and deformation inevitably occurred in the side surfaces, solder-joined portions and plated layers of the thermoelectric elements due to a difference in the thermal expansion between the thermoelectric elements and support substrates and due to internal stress being caused by a change in the temperature and external vibration and shock through the use for extended periods of time.

### SUMMARY OF THE INVENTION

It is an object of the present invention to provide a thermoelectric module featuring high junction reliability and a process for producing the same.

The present invention was finished through the discovery that cracks and deformation occurring in the thermoelectric elements can be greatly suppressed if thermal stress occurring between the support substrates and the thermal elements in the thermoelectric module and internal stress are absorbed by voids in the solder layers and that, as a result, a thermoelectric module featuring enhanced junction reliability can be obtained.

Namely, the present invention is concerned with the following matters (1) and (2).

(1) A thermoelectric module comprising support substrates, a plurality of wiring conductors formed on the opposing surfaces of the support substrates, a plurality of thermoelectric elements, and solder layers formed between said wiring conductors and said thermoelectric elements, wherein the total projected area (Sv) of voids contained in said solder layers projected onto the surfaces of the support substrates on the sides where the solder layers are in contact via the wiring conductors is from 1 to 20% of the total area (St) of the surfaces on where the solder layers are in contact with the wiring conductors.

(2) A process for producing a thermoelectric module having at least support substrates, a plurality of wiring conductors formed on the opposing surfaces of the support substrates and a plurality of thermoelectric elements, by applying a solder paste containing a void-forming agent onto the surfaces of either the wiring conductors or the thermoelectric elements in the thermoelectric module, and joining said wiring conductors and said thermoelectric elements together by the heat treatment.

The thermoelectric module according to the present invention, usually, possesses two pieces of opposing support substrates, and the plurality of wiring conductors are secured to the opposing surfaces of the support substrates. Further, the plurality of thermoelectric elements are secured to the wiring conductors by using solder layers so as to be held by the support substrates. The plurality of thermoelectric elements include N-type thermoelectric elements and P-type thermoelectric elements which are alternately arranged and are electrically connected in series through the wiring conductors.

According to the present invention, a feature resides in that the total projected area (Sv) of voids contained in the solder layers projected onto the surfaces of the support substrates on the sides where the solder layers are in contact via the wiring conductors is from 1 to 20% of the total area (St) of the surfaces on where the solder layers are in contact with the wiring conductors. The total projected area (Sv) of voids is a total value (Sv) of the projected areas of voids obtained by the projection of a parallel ray of light perpendicularly to the surfaces (I) of the support substrates from the sides of the surfaces (II) of the support substrates facing the surfaces (I) of the support substrates on the sides that are contacting via the wiring conductors. The areas and average diameter of voids can learned by the non-destructive measurement such as taking an X-ray photograph or observing a scanning-type electron microphotograph.

The total area (St1) where the solder layer is in contact with the wiring conductors is usually nearly the same as the total area (St2) where the solder layer is in contact with the thermoelectric elements. When the total area (St1) is different from the total area (St2), however, the average area of the total area (St1) and of the total area (St2) is regarded to be the total area (St).

In the thermoelectric module of the present invention, it is desired that the solder layer has a thickness over a range of from 10 to 50 μm. The solder layer having a thickness in this range is sufficient for containing voids; i.e., due to voids, the solder layer is allowed to undergo elastic deformation to further enhance the reliability of the thermoelectric module.

It is desired that the voids have an average diameter of from 1 to 100 μm. With the average diameter lying within this range, the voids contained in the solder layer do not deteriorate the junction strength, and the thermoelectric module exhibits further improved reliability.

In case elliptic voids are contained in the projected shapes in the present invention, a maximum long-axis diameter of voids is regarded to be the void diameter, and the average diameter of voids is found from an average value found from various void diameters.

It is desired that the voids are of a spherical shape but may be of a flat shape.

It is further desired that the voids have nearly a circular shape when they are projected onto the surfaces of the support substrates on the side that are in contact via the electrodes. This works to effectively absorb the thermal stress that generates, to prevent the occurrence of cracks from the edges of voids and to further enhance the reliability of the thermoelectric module.

It is desired that the solder layer is formed of an Sn—Sb solder and/or an Au—Sn solder. Then, the solder layer containing voids effectively undergoes elastic deformation to further enhance the reliability of the thermoelectric module.

It is further desired that the thermoelectric elements contain at least two or more kinds of elements selected from the group consisting of Bi, Sb, Te and Se. This further enhances the characteristics of the thermoelectric elements to make it possible to fabricate a thermoelectric module that exhibits enhanced cooling performance.

It is desired that the thermoelectric elements are provided with a plated layers on the surfaces that come in contact with the solder layer.

By providing the thermoelectric elements with the plated layer, wettability can be enhanced relative to the solder paste and, as a result, the junction strength can be improved between the thermoelectric elements and the solder layer. As the plated layer, there can be used nickel and/or gold.

It is particularly desired that nickel-plated layer is placed on the thermoelectric elements and gold is further plated thereon.

According to a process for producing a thermoelectric module according to the present invention, a solder paste containing a solder powder and a void-forming agent is prepared, the solder paste is applied onto either the thermoelectric elements or the wiring conductors or onto both of them, and the thermoelectric elements and the wiring conductors are joined together by the heat treatment. Thus, the thermoelectric module of the invention is produced easily and at a low cost.

It is particularly desired that the void-forming agent is a resin having a melting point lower than that of the solder powder. Therefore, the void-forming agent can be volatilized during the heat treatment for forming the solder layer thereby to form bubbles of a desired size.

It is further desired that the solder powder has a melting point which is not higher than 400° C. This prevents the thermoelectric elements from exhibiting deteriorated characteristics due to the heat treatment, and makes it easily to maintain excellent characteristics and reliability.

### BRIEF DESCRIPTION OF THE DRAWINGS

FIG. 1 is a perspective view schematically illustrating a thermoelectric module; and

FIG. 2 is a sectional view illustrating, on an enlarged scale, a thermoelectric element junction portion in the thermoelectric module of the present invention.

### DETAILED DESCRIPTION OF THE INVENTION

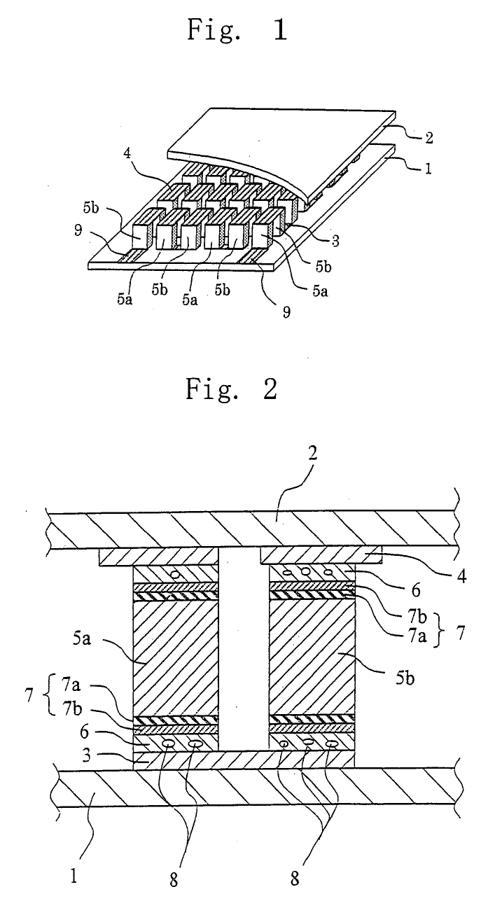

In a thermoelectric module of the present invention, as shown in FIG. 1, wiring conductors 3 and 4 are provided on the opposing surfaces of support substrates 1 and 2, and a plurality of thermoelectric elements 5 are held by the wiring conductors 3 and 4, the plurality of thermoelectric elements 5 including N-type thermoelectric elements 5a and P-type thermoelectric elements 5b which are alternately arranged and electrically connected in series. The N-type thermoelectric elements 5a and the P-type thermoelectric elements 5b are arranged in a plurality of pairs.

The plurality of pairs of thermoelectric elements 5 in FIG. 1 are secured to the support substrates 1 and 2 via the wiring conductors 3 and 4. Namely, referring to FIG. 2, the junction portions of the wiring conductors 3, 4 and the thermoelectric elements 5a, 5b are such that pairs of the N-type thermoelectric elements 5a and the P-type thermoelectric elements 5b are alternately secured to the surfaces of the wiring conductors 3 and 4 via solder layers 6 and plated layers 7 (Ni-plated layers 7a, Au-plated layers 7b), and are electrically connected in series in order of PNPNPN, so as to absorb the heat or to generate the heat depending upon the direction of a DC electric current supplied through lead wires connected to external connection terminals 9.

The thermoelectric module used for the cooling has, so far, been such that the support substrate 2 is in contact with a source of heat, and the support substrate 1 is left to cool or is cooled, producing a temperature differential between the support substrates 1 and 2. Here, the support substrates 1, 2, the thermoelectric elements 5 and the solder layers 6 have different coefficients of thermal expansion each other. When they are integrally fabricated together, therefore, a stress (thermal stress) is produced due to a large distortion stemming from differences in the thermal expansion, whereby cracks and peeling occur in the thermoelectric elements 5 and in the solder layers 6, causing degradation in the characteristics of the thermoelectric elements 5 and in the durability of the solder layers 6.

According to the present invention, it is important that the solder layers 6 contain voids 8. Besides, it is important that when the total projected area (Sv) of the whole voids contained in the solder layers 6 projected onto the surfaces of the support substrates 1 and 2 on the side where the solder layers are in contact via the wiring conductors 4 is denoted by Sv, and the total area of the surfaces on where the solder layers 6 are in contact with the wiring conductors is denoted by St, then, the ratio [(Sv/St)×100] of the total projected area Sv to the total area St of the solder layers 6 is from 1 to 20%.

The total area of the surfaces where the solder layers 6 are in contact with the wiring conductors 4 can also be found by measuring the areas of voids projected onto the opposing surfaces of the support substrates 1 and 2 by the same method as that of projecting the voids onto the support substrates.

Upon making voids 8 of a particular amount present in the solder layers 6, the thermal stress that is generated can be effectively absorbed by the solder layers 6, preventing a decrease in the performance factor caused by cracks in the thermoelectric elements 5, preventing the generation of heat due to increased contact resistance stemming from cracks and peeling in the solder layers 6, preventing such problems as defective conduction of current, and markedly improving reliability of the thermoelectric module.

In the present invention, the factor of thermoelectric performance, a figure of merit (Z) is evaluated by a method described below.

That is, the figure of merit (Z) is calculated according to the formula Z=S²/σk (S is a Seebeck coefficient, σ is a resistivity and k is a thermal conductivity), and is used as an initial value. Then, the thermoelectric module is exposed to an atmosphere of −40° C. to 100° C. at an interval of 30 minutes, and the thermoelectric performance is measured after the above operation is repeated 5000 cycles to evaluate a change from the initial value.

In order to decrease the change in the factor of performance and to improve reliability against the shock, in particular, it is desired that the area ratio of voids (Sv/St) is, desirably, not smaller than 3% and, particularly, not smaller than 5% and is, desirably, not larger than 18% and, particularly, not larger than 15%.

When an area of the solder layer 6 projected onto the support substrates 1 and 2 is not smaller than 1 cm², it is desired that the number of voids 8 is not smaller than one per square centimeter, and, more preferably, more than one per square centimeter, further preferably, not less than ten, more preferably, not less than fifty and, most preferably, not less than a hundred per square centimeter. With voids being made present at such a ratio, the stress is more effectively absorbed, and reliability of the thermoelectric module is improved.

From the standpoint of easy handling of the void-forming agent, it is desired that the voids 8 have an average diameter of, preferably, not smaller than 1 μm, more preferably, not smaller than 5 μm and, particularly preferably, not smaller than 10 μm. From the standpoint of maintaining the junction strength, on the other hand, it is desired that the average diameter of the voids 8 is, preferably, not larger 80 μm, more preferably, not larger than 50 μm, particularly preferably, not larger than 30 μm and, most desirably, not larger than 20 μm.

Upon setting the average diameter of voids 8 as described above, the voids 8 are contained while maintaining the junction strength of the solder layer, and the thermoelectric module exhibits further improved reliability.

It is desired that the voids 8 have a nearly spherical shape. The same effect, however, is also obtained even when the spherical shape is smashed into a flat shape.

It is further desired that the voids 8 have a nearly circular shape when they are projected onto the support substrates.

When the voids as projected onto the support substrate 1 have a shape close to the circular shape, heat that is generated is effectively absorbed and stress is easily prevented from concentrating. This effectively prevents the occurrence of cracks starting from the edges of voids 8, and the thermoelectric module exhibits further improved reliability.

When formed flat, the voids 8 may have an elliptic shape in cross section (elliptic sectional shape on a plane perpendicular to the support substrates 1 and 2), or may have a shape close to a flat plate in cross section in most of the portions excluding both ends and forming part of the elliptic shape at both ends.

The solder paste used in the present invention usually exhibits little wettability to the thermoelectric elements 5. In order to improve the wettability, therefore, it is desired to provide the thermoelectric elements 5 with a plated layer 7 that exhibits high wettability to the solder paste. For example, a layer 7 is provided on the surfaces of the thermoelectric elements 5, the plated layer 7 including a nickel layer 7a plated maintaining a thickness of 1 to 40 μm and an Au layer 7b plated thereon maintaining a thickness of 0.01 to 10 μm so as to come in contact with the solder layer. It is thus made possible to improve wettability to the solder paste, to maintain high workability and to enhance the adhesion strength and reliability.

It is desired that the solder layer 6 has a thickness which is, desirably, 10 to 50 μm, more preferably, 15 to 45 μm, particularly preferably, 20 to 40 μm and, most preferably, 25 to 35 μm. Upon setting the above thickness range, it becomes easy to contain a plurality of voids, enabling the solder layer 6 to undergo elastic deformation to absorb thermal stress, which is effective in improving the reliability of the thermoelectric module.

It is desired that the solder layer 6 is formed of an Sn—Sb solder containing not less than 90% of Sn and not more than 10% of Sb, or an Au—Sn solder containing not less than 60% of Au and not more than 40% of Sn. Use of the above-mentioned solder enables the solder layer 6 containing voids to undergo elastic deformation, contributing to further improving reliability of the thermoelectric module.

It is desired that the thermoelectric elements 5a and 5b contain at least two or more kinds of elements selected from the group consisting of Bi, Sb, Te and Se. It is particularly desired that an A₂B₃-type intermetallic compound and a solid solution thereof are contained. It is here desired that the A₂B₃-type intermetallic compound is a semiconductor crystal in which A is Bi and/or Sb and B is Te and/or Se, and, particularly, that the composition molar ratio (B/A) is 1.4 to 1.6 from the standpoint of improving thermoelectric characteristics at room temperature.

It is desired that the A₂B₃-type intermetallic compound is at least any one selected from the known compounds Bi₂Te₃, Sb₂Te₃ and Bi₂Se₃, and the solid solution is Bi₂Te₃₋ₓSeₓ (x=0.05 to 0.25) which is a solid solution of Bi₂Te₃ and Bi₂Se₃ or BiₓSb₂₋ₓTe₃ (x=0.1 to 0.6) which is a solid solution of Bi₂Te₃ and Sb₂Te₃.

When the N-type thermoelectric elements 5a are to be produced, it is desired that a halogen element such as I, Cl or Br is contained as a dopant so that the intermetallic compound is efficiently transformed into a semiconductor. From the standpoint of transforming into the semiconductor, it is desired that the halogen element is contained in an amount of 0.01 to 5 parts by weight and, particularly, 0.01 to 0.1 part by weight per 100 parts by weight of the starting intermetallic compound.

When the P-type thermoelectric elements 5b are to be produced, on the other hand, it is desired that Te is contained to adjust the carrier concentration. This makes it possible to improve the thermoelectric characteristics like in the N-type thermoelectric elements 5a.

The thermoelectric elements 5 exhibit further excellent reliability when their hardness is not smaller than 0.5 GPa. Namely, deformation due to vibration and shock as well as damage due to deformation can be prevented during the assembling of the module or while the thermoelectric module is being used. In order to further improve the mechanical reliability, therefore, it is desired that the hardness is, desirably, not smaller than 0.5 GPa and, more preferably, not smaller than 0.8 GPa.

The hardness referred to here stands for the micro-Vicker's hardness, and is measured by using a micro-Vicker's hardness tester (model: HMV-2000 manufactured by Shimazu Seisakusho Co.) by applying a load of 25 gf for 15 seconds.

It is further desired that the N-type and P-type thermoelectric elements 5a and 5b have resistivities of not larger than 5×10⁻⁵ Ωm and, particularly, not larger than 1.5×10⁻⁵ Ωm. This suppresses the Joule heat generated in the thermoelectric element 5 and helps accomplish efficient cooling.

The thus constituted thermoelectric module exhibits excellent mechanical strength and cooling ability, and features high reliability, and can be used as electronic cooling elements in the optical detectors and in the apparatus for producing semiconductors, can be used for maintaining constant the temperature of the semiconductor laser and of the semiconductor integrated circuits, and can be used for freon-free small refrigerators.

Next, described below is a process for producing the thermoelectric module.

To produce the thermoelectric elements, first, a powdery starting material comprising a thermoelectric semiconductor is prepared. There is no particular limitation on the powdery starting material if it is a starting powder comprising chiefly a compound containing at least two kinds of elements selected from Bi, Sb, Te and Se. Here, however, it is particularly desired that the starting material contains at least any one of Bi₂Te₃, Bi₂Se₃ or Sb₂Te₃. This lowers the probability of deviation in the composition, and makes it possible to obtain a sintered product having more homogeneous composition and texture.

When, for example, (Bi₂Te₃)₂₀(Sb₂Te₃)₈₀ is to be produced as the P-type thermoelectric element 5b, Bi₂Te₃ and Sb₂Te₃ may be used being mixed together at a ratio of 2 to 8. Further, when (Bi₂Te₃)₉₅(Bi₂Se₃)₅ is to be produced as the N-type thermoelectric element 5a, Bi₂Te₃ and Bi₂Se₃ may be used being mixed together at a ratio of 95 to 5. Use of the above compositions suppresses deviation in the composition. Upon mixing them together to a sufficient degree, further, homogeneity of the starting powder is easily maintained.

It is further desired that the starting powders have purities of not lower than 99.9% by weight, particularly, not lower than 99.99% by weight and, more particularly, not lower than 99.999% by weight. The impurities contained in the starting powders tend to deteriorate the semiconductor characteristics and the thermoelectric characteristics. To produce the thermoelectric elements 5 having stable and high performance, therefore, it is desired that the starting powders have purities as described above.

In producing the N-type thermoelectric elements 5a, it is desired to add a compound containing halogen such as HgBr₂ or SbI₃ in order to adjust the carrier concentration as a dopant. This makes it possible to obtain stable semiconductor characteristics.

The above compound powders are mixed together to obtain a desired composition which, as desired, is molded and is fired by a known firing method such as hot-press method or SPS (discharge plasma sintering) to obtain a sintered product thereof. As desired, in this case, the firing is conducted in a reducing atmosphere such as a hydrogen gas in order to remove oxygen from the starting powders and to improve properties of the sintered product.

Next, the ingot-like sintered product is sliced into wafers by using a wire saw or a dicing saw. Then, nickel-plated layers 7a are formed maintaining a thickness of 1 to 40 μm on both surfaces of the wafer-like sintered product facing the wiring conductors. Since the thermoelectric elements are formed of a semiconductor, a non-electrolytic plating is suited for plating the nickel layers 7a on the thermoelectric elements. Well-known examples of the non-electrolytic nickel plating include the one of the Ni—B type and the one of the Ni—P type. Either one of them may be employed provided the adhesion is accomplished to a sufficient degree.

Upon forming Au-plated layers 7b on the nickel-plated layers 7a, enhanced wettability is exhibited to the solder paste and, as a result, junction strength to the solder layers 6 and reliability are easily improved. It is desired that the Au-plated layers 7b have a thickness of 0.01 to 10 μm by taking into consideration the cost of the material and a drop in the workability due to the ductility of Au in addition to wettability.

The Au-plated layers 7b may be formed by either the generally employed electrolytic plating method or the non-electrolytic plating method after the nickel-plated layers have been formed. The thicknesses of the plated layers 7a and 7b can be easily measured by observing the cross sections of the plated thermoelectric element 5 through an electron microscope at a magnification of several thousand times.

Next, the wafer-like sintered product provided with the layers 7 inclusive of the nickel-plated layers 7a and the Au-plated layers 7b, is diced by a customary method so as to be finished into chip-like thermoelectric elements 5 that are to be mounted on the support substrates 1 and 2.

Instead of producing the above sintered product, there may be produced an ingot-like thermoelectric semiconductor crystal by a melt-production method, which is then worked to produce single-crystalline thermoelectric elements 5.

Next, the thermoelectric elements 5 that are obtained are joined, through the solder layer 6, to the wiring conductor 4 on the support substrate 2 that is separately provided. It is important that the voids 8 are formed in the solder layer 6 at the time of junction.

As means for forming voids 8 according to the present invention, a void-forming agent is added in advance to the solder paste so as to be sublimated to form bubbles (voids) when the solder reflows. That is, a solder paste containing a solder powder and the void-forming agent is prepared, and is applied onto the surfaces of the wiring conductors 3 and 4 formed on the support substrates 1 and 2. Then, the thermoelectric elements 5 are placed on the layers of the solder paste followed by heat treatment to join them.

It is desired that the conditions for applying the solder paste and the soldering conditions are so adjusted that the solder layer after the heat treatment possesses a thickness of 10 to 50 μm. In order to prevent the deterioration in the characteristics of the thermoelectric elements due to the heat treatment, further, it is desired that the solder powder has a melting point which is not higher than 400° C.

Any void-forming agent can be used for the present invention provided it sublimates when the solder reflows, i.e., provided it has a melting point lower than that of the solder powder. For example, there can be used a paraffin wax or a solid resin like polyvinyl alcohol.

The size and shape of voids can be controlled relying upon the size and shape of the void-forming agent. When it is desired to form the voids in nearly a spherical shape or a flat shape by smashing the spheres, there may be employed the void-forming agent of a spherical shape or an elliptic shape. When it is desired to form the voids in nearly a cylindrical shape, there may be employed the void-forming agent of the cylindrical shape.

Upon containing the voids 8, the solder layer 6 is allowed to undergo elastic deformation to absorb stress stemming from a difference in the thermal expansion between the thermoelectric elements 5 and the support substrates 1, 2. By using, as the junction layer, the Sn—Sb solder having a melting point of not higher than 400° C. and containing not less than 90 wt % of Sn and not more than 10 wt % of Sb or the Au—Sn solder having a melting point of not higher than 400° C. and containing not less than 60 wt % of Au and not more than 40 wt % of Sn, it is made possible to provide a thermoelectric module which features an extended product life in a practical temperature range (−40° C. to 85° C.) though it does not mean that the stress can be absorbed to an infinite degree.

The thus obtained solder layer 6 can have a junction strength of not smaller than 8 MPa, particularly, not smaller than 10 MPa and, more particularly, not smaller than 12 MPa.

To summarize the advantages obtained by the invention, there is realized a thermoelectric module featuring a high junction reliability among the thermoelectric elements and the support substrates in which voids are formed in the solder layers formed among the thermoelectric elements and the wiring conductors to join them together, wherein the total projected area (Sv) of voids projected onto the surfaces of the support substrates on the side where the solder layers are in contact via the wiring conductors is from 1 to 20% of the total area (St) of the surfaces on where the solder layers are in contact with the wiring conductors.

In particular, there is obtained a thermoelectric module featuring very high junction reliability by selecting the area ratio (Sv/St) to be 1 to 20%, by using the Sn—Sb solder or the Au—Sn solder as the solder layers, and by controlling the thickness of the solder layers and the average diameter of voids.

### EXAMPLES

Bi₂Te₃, Sb₂Te₃ and Bi₂Se₃ having an average particle diameter of 35 μm and purities of not smaller than 99.99% by weight were prepared as starting materials for the thermoelectric elements. These compounds were so mixed as to be Bi₂Te_{2.85}Se_{0.15} for those of the N-type and Bi_{0.4}Sb_{1.6}Te₃ for those of the P-type. To the mixture of the N-type was further added, as a dopant, SbI₃ in an amount of 0.09 parts by weight per 100 parts by weight of the intermetallic compound.

The above mixture was press-molded into an article having a diameter of 20 mm and a thickness of 5 mm, and was fired in a hydrogen gas stream at 400° C. for 5 hours to obtain a calcined article.

Next, the calcined article was set into a cylindrical carbon dies, held by compression/current-feeding punches made of carbon from the upper and lower sides, set into a sintering furnace, and the interior of the furnace was substituted with an argon gas to increase the density of the sintered product. The firing was conducted at 450° C. under a pressure of 50 MPa for 10 minutes to obtain an ingot-like sintered article measuring 30 mm in diameter and 3 mm in thickness.

The ingot-like sintered article possessed a relative density of not lower than 98.2% and a micro-Vicker's hardness (Hv) of as very high as 0.71 GPa or greater. Then, by using a wire saw and a plane grinder, the ingot was cut into thin wafers having a thickness of 0.9 mm.

Next, the nickel-plated layer 7a was formed maintaining a thickness of 3 μm on the sintered wafer by the Ni—B type non-electrolytic plating. The nickel-plated layer 7a was formed by the activation treatment with palladium chloride by using a plating solution containing nickel chloride and a boron hydroxide compound as a reducing agent at such a ratio that the amount of nickel was 98% by weight while the amount of boron was 2% by weight.

Further, the Au layer 7b was formed on the nickel layer 7a by plating Au thereon. The Au-plated layer 7b possessed a thickness of 0.2 μm.

The sintered wafer on which has been plated the layer 7 comprising the nickel-plated layer 7a and the Au-plated layer 7b, was subjected to the dicing to obtain a thermoelectric element 5 measuring 0.7 mm high, 0.7 mm wide and 0.9 mm long.

Next, the insulating support substrates 1 and 2 of alumina ceramic measuring 10 mm long, 10 mm wide and 0.3 mm thick were prepared, copper plates to serve as wiring conductors 3 and 4 were joined to the opposing surfaces of the support substrates, a creamy solder paste was applied onto the wiring conductors 3 and 4 which are the copper plates by using a metallic plate, and the reflow processing was executed while holding the thermoelectric elements 5 by the support substrates 1 and 2.

The solder paste was the one comprising the solder powder and any one, as the void-forming agent, of (1) a paraffin wax of a spherical shape measuring 1 to 50 μm, (2) a paraffin wax of a cubic shape having a side of 3 μm, (3) a paraffin wax of a cylindrical shape having a diameter of 3 μm and a length of 3 μm, or (4) a paraffin wax of an oval shape having a maximum diameter of 3 μm and a length of 3 μm.

By using the thus obtained N-type thermoelectric elements 5a of a number of 30 and P-type thermoelectric elements 5b of a number of 30, there was obtained a thermoelectric module shown in FIGS. 1 and 2.

The average diameter of voids in the solder layer 6 and the area ratio (Sv/St) were measured in a non-destructive matter by taking an X-ray photograph, while, the cross section of the solder layer was observed from a scanning electron microphotograph to confirm the shape in effecting the correction. Here, the average diameter and the area ratio are the shape projected onto the support substrates and the area thereof. The average diameter of voids is expressed by a maximum length.

A shock pulse of 2000 G/0.5 msec was repetitively imparted to the thermoelectric module in the X-, Y- and Z-directions, and the number of times until the deterioration in the appearance or the thermoelectric performance was observed was regarded to be a shock resistance.

Further, the thermoelectric module was measured for its junction strength. The junction strength was measured in a manner of measuring a force necessary for peeling off the support substrate soldered to the thermoelectric elements by using a universal testing machine, Model 1125, manufactured by Instron Co.

Further, the thermoelectric performance was measured. Namely, the figure of merit (Z) was calculated according to the formula Z=S²/σk (S is a Seebeck coefficient, σ is a resistivity, and k is a thermal conductivity), and was used as an initial value. Next, the thermoelectric module was exposed to an atmosphere of −40° C. to 100° C. at an interval of 30 minutes. After the above operation was repeated 5000 times, the thermoelectric performance was measured to evaluate a change from the initial value. The thermal conductivity was measured by a laser flush method, and the Seebeck coefficient and the resistivity were measured by using a thermoelectric performance-evaluating apparatus manufactured by Shinkuriko Co. under a temperature condition of 20° C. The results were as shown in Table 1.

TABLE 1

| | Solder components | | | | | | Solder layer | | | |
|---|---|---|---|---|---|---|---|---|---|---|
| | Composition | | | | | | | With Voids | | |
| | | Concen- | | Concen- | Melting | Void | Thick- | | Average | Area |
| Sample | | tration | | tration | point | agent, | ness | | diameter | ratio |
| No. | Kind | (mol %) | Kind | (mol %) | (° C.) | shape | (μm) | Shape | (μm) | (%) |
| *1 | Sn | 95 | Sb | 5 | 240 | spherical | 30 | flat | 50 | 0 |
| 2 | Sn | 95 | Sb | 5 | 240 | spherical | 30 | flat | 50 | 1.2 |
| 3 | Sn | 95 | Sb | 5 | 240 | spherical | 30 | flat | 50 | 3.2 |
| 4 | Sn | 95 | Sb | 5 | 240 | spherical | 30 | flat | 50 | 5.2 |
| 5 | Sn | 95 | Sb | 5 | 240 | spherical | 30 | flat | 50 | 8.0 |
| 6 | Sn | 95 | Sb | 5 | 240 | spherical | 30 | flat | 50 | 10.0 |
| 7 | Sn | 95 | Sb | 5 | 240 | spherical | 30 | flat | 50 | 12.0 |
| 8 | Sn | 95 | Sb | 5 | 240 | spherical | 30 | flat | 50 | 16.0 |
| 9 | Sn | 95 | Sb | 5 | 240 | spherical | 30 | flat | 50 | 19.2 |
| 10 | Sn | 95 | Sb | 5 | 240 | spherical | 50 | flat | 1 | 4.8 |
| 11 | Sn | 95 | Sb | 5 | 240 | spherical | 50 | flat | 10 | 4.8 |
| 12 | Sn | 95 | Sb | 5 | 240 | spherical | 50 | flat | 20 | 4.8 |
| 13 | Sn | 95 | Sb | 5 | 240 | spherical | 50 | flat | 50 | 4.8 |
| 14 | Sn | 95 | Sb | 5 | 240 | spherical | 50 | flat | 100 | 4.8 |
| 15 | Sn | 95 | Sb | 5 | 240 | spherical | 10 | flat | 10 | 9.6 |
| 16 | Sn | 95 | Sb | 5 | 240 | spherical | 20 | flat | 10 | 9.6 |
| 17 | Sn | 95 | Sb | 5 | 240 | spherical | 40 | flat | 10 | 9.6 |
| 18 | Sn | 95 | Sb | 5 | 240 | spherical | 50 | flat | 10 | 9.6 |
| 19 | Au | 80 | Sn | 20 | 280 | cubic | 30 | cubic | 10 | 9.6 |
| 20 | Au | 80 | Sn | 20 | 280 | oval | 30 | flat | 10 | 9.6 |
| 21 | Au | 80 | Sn | 20 | 280 | cylindrical | 30 | cylindrical | 10 | 9.6 |
| 22 | Au | 50 | Sn | 50 | 420 | spherical | 30 | spherical | 10 | 9.6 |
| 23 | Au | 60 | Sn | 40 | 350 | spherical | 30 | flat | 10 | 9.6 |
| 24 | Au | 80 | Sn | 20 | 280 | spherical | 30 | flat | 10 | 9.6 |

| | Themo module | | | |
|---|---|---|---|---|
| | Shock | Junction | Performance factor | |
| Sample | resistance | strength | Initial value | Change |
| No. | (times) | (MPa) | (×10⁻³/K) | (%) |
| *1 | 28 | 12 | 3.3 | 8.7 |
| 2 | 1528 | 12 | 3.3 | 3.1 |
| 3 | 2005 | 13 | 3.3 | 0.8 |
| 4 | 2307 | 13 | 3.3 | 0.6 |
| 5 | 2457 | 12 | 3.3 | 0.5 |
| 6 | 2542 | 13 | 3.3 | 0.4 |
| 7 | 2472 | 13 | 3.3 | 0.5 |
| 8 | 2288 | 13 | 3.3 | 1.1 |
| 9 | 1890 | 12 | 3.3 | 2.5 |
| 10 | 2334 | 11 | 3.3 | 0.4 |
| 11 | 2471 | 12 | 3.3 | 0.4 |
| 12 | 2374 | 12 | 3.3 | 0.6 |
| 13 | 2010 | 12 | 3.3 | 1.5 |
| 14 | 1028 | 12 | 3.3 | 3.9 |
| 15 | 1132 | 12 | 3.3 | 4.0 |
| 16 | 1535 | 12 | 3.3 | 3.0 |
| 17 | 1543 | 12 | 3.3 | 3.0 |
| 18 | 1267 | 12 | 3.3 | 3.8 |
| 19 | 1047 | 12 | 3.3 | 4.7 |
| 20 | 1345 | 12 | 3.3 | 3.6 |
| 21 | 1282 | 12 | 3.3 | 3.8 |
| 22 | 1006 | 8 | 3.3 | 4.5 |
| 23 | 1027 | 9 | 3.3 | 4.3 |
| 24 | 1314 | 12 | 3.3 | 3.7 |

Samples marked with * lie outside the scope of the invention.

It was learned that the samples Nos. 2 to 24 having area ratios of voids of 1 to 20% were capable of withstanding the shocks of not less than 1500 times and the temperature cycles of not less than 5000 times, and were very highly reliable exhibiting changes in the figure of merit (Z) of not larger than 5%.

In particular, the samples Nos. 3 to 8 having an average diameter of 50 μm and area ratios of voids of 3 to 18% exhibited shock resistances of not smaller than 2000 times and changes in the figure of merit (Z) of not larger than 2%. Further, the samples Nos. 3 to 8 having area ratios of voids of 3 to 18% exhibited shock resistances of not smaller than 2300 times and changes in the figure of merit (Z) of not larger than 1%.

On the other hand, the sample No. 1 without void in the solder layer lying outside the scope of the invention exhibited a shock resistance of 28 times and a change in the figure of merit (Z) of 8.7%, permitting the thermoelectric performance to be greatly deteriorated through the temperature cycles and offering poor reliability.

1. A thermoelectric module comprising support substrates, a plurality of wiring conductors formed on the opposing surfaces of the support substrates, a plurality of thermoelectric elements, and solder layers formed between said wiring conductors and said thermoelectric elements, wherein the total projected area (Sv) of voids contained in said solder layers projected onto the surfaces of the support substrates on the side where the solder layers are in contact via the wiring conductors is from 1 to 20% of the total area (St) of the surfaces on where the solder layers are in contact with the wiring conductors.

2. A thermoelectric module according to claim 1, wherein said thermoelectric elements are provided with plated layers on the surfaces in contact with the solder layers.

3. A thermoelectric module according to claim 2, wherein said plated layers are formed by plating with nickel and/or gold.

4. A thermoelectric module according to claim 1, wherein said solder layers have an average thickness of 10 to 50 μm.

5. A thermoelectric module according to claim 1, wherein the voids contained in said solder layers have an average diameter of 1 to 100 μm.

6. A thermoelectric module according to claim 1, wherein said voids have nearly a circular shape when they are projected onto the surfaces of the support substrates on the side in contact via said wiring conductors.

7. A thermoelectric module according to claim 1, wherein said solder layer comprises an Sn—Sb solder and/or an Au—Sn solder.

8. A thermoelectric module according to claim 1, wherein said thermoelectric elements contain at least two or more kinds of elements selected from the group consisting of Bi, Sb, Te and Se.

9. A process for producing a thermoelectric module having at least support substrates, a plurality of wiring conductors formed on the opposing surfaces of the support substrates and a plurality of thermoelectric elements, by applying a solder paste containing a void-forming agent onto the surfaces of either the wiring conductors or the thermoelectric elements in the thermoelectric module, and joining said wiring conductors and said thermoelectric elements together by the heat treatment.

10. A process for producing a thermoelectric module according to claim 9, wherein the total projected area (Sv) of voids contained in said solder layers projected onto the surfaces of the support substrates on the side where the solder layers are in contact via the wiring conductors is from 1 to 20% of the total area (St) of the surfaces on where the solder layers are in contact with the wiring conductors.

11. A process for producing a thermoelectric module according to claim 9, wherein said paste is prepared by using at least a solder powder and a void-forming agent, the void-forming agent being a resin having a melting point lower than that of the solder powder.

12. A process for producing a thermoelectric module according to claim 11, wherein said solder powder has a melting point which is not higher than 400° C.
